(19) United States
(12) Patent Application Publication
(10) Pub. No.: US 2026/0031783 A1
(43) Pub. Date: Jan. 29, 2026

(54) PIEZOELECTRIC ELEMENT AND ELECTRONIC DEVICE

(71) Applicant: NITTO DENKO CORPORATION, Ibaraki-shi, Osaka (JP)

(72) Inventors: Yuzuki AOKI, Ibaraki-shi, Osaka (JP); Daisuke NAKAMURA, Ibaraki-shi, Osaka (JP); Gaku TSUBURAOKA, Ibaraki-shi, Osaka (JP); Koichi SAKATA, Ibaraki-shi, Osaka (JP); Takahiro NAKAI, Ibaraki-shi, Osaka (JP)

(21) Appl. No.: 19/116,001

(22) PCT Filed: Sep. 13, 2023
(86) PCT No.: PCT/JP2023/033440

§ 371 Date: Mar. 27, 2025

(30) Foreign Application Priority Data
Sep. 30, 2022 (JP) 2022-157636

(51) Int. Cl. H03H 9/02; H03H 3/02; H03H 9/17

(52) U.S. Cl. CPC H03H 9/02031; H03H 3/02; H03H 9/173; H03H 9/175; H03H 9/176; H03H 2003/025

(57) ABSTRACT

A piezoelectric element according to the present invention includes: a first electrode, a piezoelectric layer containing a piezoelectric material doped with Mg, and a second electrode, which are laminated in this order on a support substrate; and an Mg deficiency preventing layer configured to reduce an outflow of Mg from the piezoelectric layer, the Mg deficiency preventing layer being provided at at least one of a location between the first electrode and the piezoelectric layer, and a location between the piezoelectric layer and the second electrode.

### TECHNICAL FIELD

The present invention relates to a piezoelectric element and an electronic device.

### BACKGROUND ART

Piezoelectric elements include a piezoelectric layer made of a piezoelectric material. Piezoelectric elements are used in electronic devices as electronic components, such as, for example, sensors, such as pressure sensors, acceleration sensors, Acoustic Emission (AE) sensors for detecting elastic waves, and the like, high-frequency filters, piezoelectric actuators, Radio Frequency (RF) filters, and the like, to take advantage of the piezoelectric effect of the piezoelectric layer.

As a piezoelectric element, for example, a piezoelectric element including a piezoelectric layer containing a sub-component, such as Mg, in a wurtzite piezoelectric material, such as ZnO, between electrodes formed on substrates is disclosed (for example, see PTL 1).

ZnO doped with Mg as a sub-component (MgZnO) has almost no trade-off relationship between the K factor required in the 5G high-frequency band and the Q factor indicating filter steepness, and can satisfy both the K factor and the Q factor simultaneously with respect to the concentration of Mg to be added to ZnO. Therefore, its use as a piezoelectric material to be used in the high-frequency band is being studied.

### CITATION LIST

### Patent Literature

PTL 1: International Publication No. WO 2022/163722

### SUMMARY OF THE INVENTION

### Technical Problem

However, the piezoelectric element of PTL 1 has a problem that Mg sublimation from the surface of the piezoelectric layer causes voids in the surface of the piezoelectric layer, which may cause variations in the piezoelectric characteristics of the piezoelectric layer.

An object of the present invention is to provide a piezoelectric element capable of maintaining piezoelectric characteristics.

### Solution to the Problem

An embodiment of the piezoelectric element according to the present invention includes:
a first electrode, a piezoelectric layer containing a piezoelectric material doped with Mg, and a second electrode, which are laminated in this order on a support substrate; and
an Mg deficiency preventing layer configured to reduce an outflow of Mg from the piezoelectric layer, the Mg deficiency preventing layer being provided at at least one of a location between the first electrode and the piezoelectric layer, and a location between the piezoelectric layer and the second electrode.

### Advantageous Effects of the Invention

One embodiment of the piezoelectric element according to the present invention can maintain piezoelectric characteristics.

### BRIEF DESCRIPTION OF THE DRAWINGS

FIG. 1 is a schematic cross-sectional view showing a configuration of a piezoelectric element according to an embodiment of the present invention.

FIG. 2 is a schematic cross-sectional view showing an example of another configuration of a piezoelectric element.

FIG. 3 is a schematic cross-sectional view showing an example of another configuration of a piezoelectric element.

FIG. 4 is a schematic cross-sectional view showing an example of another configuration of a piezoelectric element.

FIG. 5 is a schematic cross-sectional view showing an example of another configuration of a piezoelectric element.

FIG. 6 is a schematic cross-sectional view showing an example of another configuration of a piezoelectric element.

### DETAILED DESCRIPTION OF THE INVENTION

Embodiments of the present invention will now be described in detail. In order to facilitate understanding of the description, duplicate descriptions will be omitted by assigning the same reference numerals to the same components in the drawings. The members in the drawings might not be to scale. Unless otherwise particularly noted, the term “to” indicating a numerical range in the specification means that the numerical values described before and after the term are included as the lower limit and upper limit.

### Piezoelectric Element

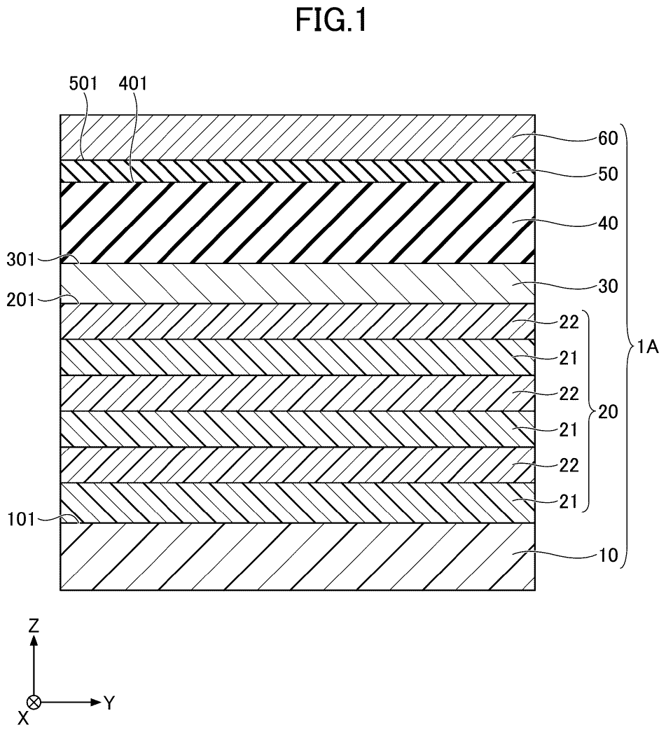

FIG. 1 is a schematic cross-sectional view showing a configuration of a piezoelectric element according to the present embodiment. As shown in FIG. 1, a piezoelectric element 1A includes a support substrate 10, an acoustic mirror layer 20, a first electrode 30, a piezoelectric layer 40, an Mg deficiency preventing layer 50, and a second electrode 60 that are laminated in this order. The piezoelectric element 1A may be formed in any shape, such as a sheet shape (film shape) and the like.

In this specification, the width direction of the piezoelectric element 1A is defined to be the X-axis direction, the length direction is defined to be the Y-axis direction, and the height (thickness) direction (vertical direction) is defined to be the Z-axis direction, using a three-dimensional orthogonal coordinate system in three axial directions (X-axis direction, Y-axis direction, and Z-axis direction). The second electrode 60 side in the Z-axis direction is defined to be located in the +Z-axis direction, and the support substrate 10 side is defined to be located in the −Z-axis direction. In the following description, for the sake of explanation, the +Z-axis direction is expressed by using terms like “upper”, “upward”, “above”, “top”, and the like, and the −Z-axis direction is expressed by using terms like “lower”, “downward”, “bottom”, and the like. However, these terms do not represent a universal vertical relationship.

The piezoelectric element 1A inhibits sublimation of Mg contained in the piezoelectric layer 40 from an upper surface 401 of the piezoelectric layer 40 with the Mg deficiency preventing layer 50 provided on the upper surface 401 of the piezoelectric layer 40. As a result, deterioration of the piezoelectric layer 40 due to generation of voids in the surface of the piezoelectric layer 40 can be inhibited, and the piezoelectric element 1A can maintain piezoelectric characteristics.

In the specification, the piezoelectric characteristics include both the amount of a voltage generated per applied stress (normal piezoelectric effect) and a rate of mechanical displacement per applied electric field (reverse piezoelectric effect).

### [Support Substrate]

As shown in FIG. 1, the support substrate 10 is a substrate on which a laminate of the acoustic mirror layer 20, the first electrode 30, the piezoelectric layer 40, the Mg deficiency preventing layer 50, and the second electrode 60 is installed, and may be flexible so as to provide flexibility to the piezoelectric element 1A.

As the material for forming the support substrate 10, any type of material may be used, as long as it can support the laminate stably. For example, a plastic substrate, a metal foil, a metal plate, a silicon (Si) substrate, an inorganic dielectric substrate, a glass substrate, and the like may be used.

When using a plastic substrate, it is preferable to use a material having flexibility to provide flexibility to the piezoelectric element 1A including the piezoelectric layer 40.

As the material for forming the plastic substrate, for example, polyethylene terephthalate (PET), polyethylene naphthalate (PEN), polycarbonate (PC), acrylic resin, cycloolefin polymer, polyamide (PA) resin, polyimide (PI) resin, polyphenylene sulfide (PPS), polytetrafluoroethylene (PTFE), diallylphthalate resin (PDAP) and the like can be used.

The support substrate 10 may be transparent, semitransparent, or opaque. Transparency means transmissivity of visible light (light having a wavelength of 380 nm to 780 nm) to allow the interior of the support substrate 10 to be visually seen from outside, and means a visible light transmittance of 40% or higher, preferably 80% or higher, and more preferably 90% or higher. The light transmittance is measured using “Plastic-Total Light Transmittance and Total Light Reflectance Determination” specified in Japanese Industrial Standards (JIS) K 7375:2008.

When light transmissivity is required of the piezoelectric element 1A, it is preferable to use PET, PEN, PC, acrylic resin, cycloolefin polymer, and the like. These materials are suitable when the piezoelectric element 1A is applied as a light-transmissive component of a touch panel and the like.

When light transmittance is not required of the piezoelectric element 1A, such as when it is applied to healthcare products, such as pulsometers, heart rate monitors, and the like, vehicle-mounted pressure detection sheets, and the like, semitransparent or opaque plastic materials may be used.

Metals such as Au, Pt, Ag, Ti, Al, Mo, Ru, Cu, and the like may be used as the material for forming the metal foil.

For example, aluminum, copper, stainless steel, tantalum, and the like may be used as the material for forming the metal plate.

For example, MgO, sapphire, and the like may be used as the material for forming the inorganic dielectric substrate.

The thickness of the support substrate 10 is not particularly limited, may be appropriately determined in accordance with the use of the piezoelectric element 1A, the material of the support substrate 10, and the like, and may be, for example, 1 μm to 150 μm. When the thickness of the support substrate 10 is 1 μm to 150 μm, the laminate including the acoustic mirror layer 20, the first electrode 30, the piezoelectric layer 40, the Mg deficiency preventing layer 50, and the second electrode 60 can be stably supported. In addition, since the warpage of the support substrate 10 can be inhibited, and the piezoelectric characteristics can be less affected by any warpage of the support substrate 10, the piezoelectric element 1A can have a desired flexibility.

In this specification, the thickness of the support substrate 10 means the length in the direction perpendicular to the surface of the support substrate 10. The method for measuring the thickness of the support substrate 10 is not particularly limited, and any measurement method can be used. The thickness of the support substrate 10 may be, for example, the thickness measured at an arbitrary location in a cross-section of the support substrate 10, or may be the average value of thickness values measured at some arbitrarily selected locations. Hereinafter, the definition of the thickness will be the same for other members.

### [Acoustic Mirror Layer]

The acoustic mirror layer 20 is provided on an upper main surface (upper surface) 101 of the support substrate 10 as shown in FIG. 1. The acoustic mirror layer 20 may be composed of an acoustic multilayer film varied in intrinsic acoustic impedance. The acoustic mirror layer 20 is a multilayer film in which at least two pairs of a high acoustic impedance layer 21 having a predetermined intrinsic acoustic impedance and a low acoustic impedance layer 22 having an intrinsic acoustic impedance lower than that of the high acoustic impedance layer 21, which are arranged alternately, are laminated.

When resonant vibration is transmitted to the acoustic mirror layer 20, the resonant vibration energy is reflected by the acoustic mirror layer 20. The speed at which the vibration wave (elastic wave) propagates through the high acoustic impedance layers 21 and the speed at which it propagates through the low acoustic impedance layers 22 are different. With a film thickness design that causes reflected waves to be strengthened by interference at each interface between the layers constituting the acoustic mirror layer 20, the resonant vibration energy is allowed to return in the direction in which the elastic wave has come to be incident thereto, without being affected by the support substrate 10, and thermal energy is allowed to escape in the direction toward the support substrate 10.

The high acoustic impedance layer 21 is formed of a material having a high density or bulk modulus, such as W, Mo, Ta₂0₅, ZnO, and the like. The low acoustic impedance layer 22 is formed of a material having a density or bulk modulus lower than that of the high acoustic impedance layer 21.

The low acoustic impedance layer 22 is formed of a material having a low density or bulk modulus, such as SiO₂. The low acoustic impedance layer 22 may be an amorphous layer or an amorphous dominant layer. By forming the low acoustic impedance layer 22 as an amorphous dominant layer, it is possible to inhibit increase in stress in the high acoustic impedance layer 21.

The high acoustic impedance layer 21 and the low acoustic impedance layer 22 are formed on the support substrate 10 by sputtering or the like.

### [First Electrode]

As shown in FIG. 1, the first electrode 30 is provided on an upper main surface (upper surface) 201 of the acoustic mirror layer 20. The first electrode 30 may be formed in a thin film shape on a part or the entire surface of the acoustic mirror layer 20, or a plurality of first electrodes 30 may be provided in parallel in a stripe pattern.

As the first electrode 30, any material having conductivity may be used. As the material, metals such as Pt, Au, Ag, Cu, Mg, Al, Si, Ti, Cr, Fe, Ni, Zn, Rb, Zr, Nb, Mo, Rh, Pd, Ru, Sn, Ir, Ta, W, and the like, metal oxides such as tin oxide, ITO (Indium Tin Oxide), IZO (Indium Zinc Oxide), IZTO (Indium Zinc Tin Oxide), IGZO (Indium Gallium Zinc Oxide), and the like may be used.

The first electrode 30 may be a transparent electrode made of a conductive material transparent to visible light. Transparency of the first electrode 30 is not essential depending on the field of application of the piezoelectric element 1A. However, when applying the piezoelectric element 1A to a display such as a touch panel, light transparency to visible light is required. When light transmissivity is required of the first electrode 30, oxide conductive films made of transparent metal oxides such as ITO, IZO, IZTO, IGZO, and the like may be used as the material.

When no light transmissivity is required of the first electrode 30, metals and the like may be used as the material, or hexagonal crystal metals having the same lattice structure as that of wurtzite may be used.

As the hexagonal crystal metals, Ti, Zr, Hf, Ru, Zn, Y, Sc, and the like may be used in combination.

From the viewpoint of suppressing irregularities and grain boundaries at the interface between the first electrode 30 and the piezoelectric layer 40, the first electrode 30 may be an amorphous film. The amorphous film suppresses formation of irregularities, and of grain boundaries, which cause leakage paths, on the surface of the first electrode 30. Moreover, the upper piezoelectric layer 40 can grow with a good crystal orientation without being affected by the crystal orientation of the first electrode 30.

The thickness of the first electrode 30 can be appropriately designed, and may be, for example, 3 nm to 300 nm. When the thickness of the first electrode 30 is 3 nm to 100 nm, the function as an electrode can be expressed, and the piezoelectric element 1A can be reduced in thickness.

### [Piezoelectric Layer]

As shown in FIG. 1, the piezoelectric layer 40 is provided on an upper main surface (upper surface) 301 of the first electrode 30. The piezoelectric layer 40 contains a piezoelectric material that is doped with Mg as a metal element in a predetermined ratio range, or may consist of a piezoelectric material doped with Mg.

It is preferable that the piezoelectric layer 40 contains a piezoelectric material as a main component. Being a main component means that the content of the piezoelectric material is 95 atom % or greater, preferably 98 atom % or greater, or more preferably 99 atom % or greater.

As the piezoelectric material, a piezoelectric material having a perovskite crystal structure (perovskite crystal material), a piezoelectric material having a wurtzite crystal structure (wurtzite crystal material), and the like can be used.

The wurtzite crystal structure is represented by a general formula AB (where A is an electro electropositive element and B is an electronegative element). The wurtzite crystal material has a hexagonal crystal unit cell, and has a polarization vector in the direction parallel to a c-axis.

As the wurtzite crystal material, it is preferable to use a material that exhibits piezoelectric characteristics equal to or greater than certain values and can be crystallized in a low-temperature process at 200° C. or lower. The wurtzite crystal material contains Zn, Al, Ga, Cd, Si, and the like as the electropositive element A indicated in the general formula AB. As the wurtzite crystal material, for example, zinc oxide (ZnO), zinc sulfide (ZnS), zinc selenide (ZnSe), zinc telluride (ZnTe), aluminum nitride (AlN), gallium nitride (GaN), cadmium selenide (CdSe), cadmium telluride (CdTe), silicon carbide (SiC), and the like can be used. Among these, ZnO is preferable as the wurtzite crystal material because it tends to be oriented along the c-axis relatively favorably even at a low temperature. One of these materials may be used alone, or two or more of these materials may be used in combination. When two or more wurtzite crystal materials are used in combination, one or more of them may be contained as the main component and the other components may be contained as optional components. In addition, respective materials may be laminated, or may be formed as a single layer using multiple targets.

It is preferable that the wurtzite crystal material contains ZnO. It is more preferable that the wurtzite crystal material is substantially composed of ZnO. It is yet more preferable that the wurtzite crystal material is composed only of ZnO. “Substantially” means that, in addition to ZnO, unavoidable impurities that may be unavoidably included during the production process may be contained.

As described above, the piezoelectric material contains Mg as a dopant metallic element. Mg may be contained in an element state or in an oxide state. As the piezoelectric material doped with Mg, a wurtzite crystal material doped with Mg is preferable. The piezoelectric material doped with Mg is more preferably ZnO doped with Mg, in order for excellent piezoelectric characteristics to be exhibited, with the K factor, which is an indicator of a piezoelectric characteristic of the piezoelectric layer 40, and the Q factor, which is an indicator of the steepness, both satisfied. That is, the piezoelectric material doped with Mg is preferably MgZnO, which is Zno doped with Mg.

The K factor is the value of the electromechanical coupling factor K. The square value (K²) of the electromechanical coupling factor K of the piezoelectric material contained in the piezoelectric layer 40 indicates the energy conversion efficiency for electrical energy, defined for piezoelectric materials. The higher the energy conversion efficiency for electrical energy, the better the operating efficiency of the piezoelectric element 1A including the piezoelectric layer 40, and the better the piezoelectric characteristics of the piezoelectric element 1A. Regarding the same material and the same composition, as the crystal orientation disorder of the piezoelectric material contained in the piezoelectric layer 40 decreases, the value K² of the piezoelectric material increases, and they gradually become constant. That is, as the crystal orientation disorder of the piezoelectric material decreases, the energy conversion efficiency of the piezoelectric material increases, and they gradually become constant, which means that the piezoelectricity becomes constant. Therefore, the greater the electromechanical coupling factor K, the greater the value K² and the higher the energy conversion efficiency of the piezoelectric material, which means that the piezoelectric material has higher piezoelectric characteristics. The greater the electromechanical coupling factor K, the smaller the crystal orientation disorder, which means a better crystal orientation property.

The Q factor is a value that indicates the sharpness (steepness) of the frequency characteristic. The greater the Q factor, the sharper the frequency characteristic appears.

The piezoelectric material may be doped with any other metal element in addition to Mg. Examples of the any other dopant metal element for the piezoelectric material include: alkali earth metals such as Ca and Sr; V, Ti, Zr, Si, Sr, and Li; and the like. These components may be contained in the element state or in the oxide state.

The content of the additive element in the piezoelectric layer 40 is not particularly limited, and may be in the range in which the piezoelectric layer 40 can have a wurtzite crystal structure. The method for measuring the content of the additive element contained in the piezoelectric layer 40 is not particularly limited as long as the content of the additive element can be measured. The content of the additive element contained in the piezoelectric layer 40 may be measured, for example, by Rutherford Back Scattering analysis (RBS) using a Pelletron 3SDH (available from NEC Corporation) as a measuring device, or by secondary ion mass spectrometry using a dynamic SIMS (D-SIMS) or the like.

The thickness of the piezoelectric layer 40 is not particularly limited, and may be any thickness that provides a sufficient piezoelectric characteristic, i.e., a polarization characteristic proportional to pressure, and enables the piezoelectric layer 40 to stably exhibit piezoelectric characteristics by reducing the occurrence of cracks or the like. The thickness of the piezoelectric layer 40 may be, for example, 50 nm to 5 μm. When the thickness of the piezoelectric layer 40 is 50 nm to 5 μm, occurrence of cracks can be avoided and sufficient piezoelectric characteristics can be exhibited.

The crystal orientation of the piezoelectric layer 40 is preferably 5° or less. When the crystal orientation is 5° or less, the piezoelectric material contained in the piezoelectric layer 40 has a good crystal orientation in the c-axis direction (c-axis orientation), and the energy conversion efficiency can be enhanced, leading to improved piezoelectric characteristics in the thickness direction of the piezoelectric layer 40. When the piezoelectric layer 40 contains ZnO as a piezoelectric material, ZnO has a wurtzite crystal structure and has a higher correlation between the crystal orientation and the piezoelectric characteristics than that of piezoelectric materials having other crystal structures. ZnO having a crystal orientation of 5° or less better facilitates enhancement of the energy conversion efficiency, and can therefore improve the piezoelectric characteristics of the piezoelectric element 1A.

The crystal orientation of the piezoelectric layer 40 can be evaluated based on the Full Width at Half Maximum (FWHM) obtained when the surface of the piezoelectric layer 40 is measured by the X-ray Rocking Curve (XRC) method. That is, the crystal orientation of the piezoelectric layer 40 is represented by the FWHM of a peak waveform of a rocking curve obtained when diffraction from the (0002) plane of the piezoelectric material crystal contained as a main component in the piezoelectric layer 40 is measured by the XRC method. When the piezoelectric material contained in the piezoelectric layer 40 has a wurtzite crystal structure such as Zno, the FWHM indicates the degree of c-axis direction orientation parallelism between crystals constituting the piezoelectric material. Therefore, the FWHM of a peak waveform of a rocking curve obtained by the XRC method can be used as an indicator of the c-axis orientation of the piezoelectric layer 40. Therefore, the smaller the FWHM of the rocking curve, the better the c-axis orientation of the piezoelectric layer 40 can be evaluated to be.

In addition, the XRC measurement of the crystal orientation of the piezoelectric layer 40 may include evaluation of the peak intensity as well, in addition to the FWHM of the rocking curve obtained by measuring diffraction from a specific crystal plane of the piezoelectric material of the piezoelectric layer 40 (e.g., the (0002) plane of a ZnO crystal). That is, the crystal orientation of the piezoelectric layer 40 may be evaluated by using, as an evaluation value, a value obtained by dividing the integrated value of the peak intensity by the FWHM. For example, the greater the evaluation value obtained by dividing the integrated value of the peak intensity by the FWHM, the better the crystal orientation of the piezoelectric layer 40 can be evaluated to be.

When two or more types of piezoelectric materials are used in combination, the piezoelectric layer 40 may be formed by laminating piezoelectric layers made of the respective piezoelectric materials.

### [Mg Deficiency Preventing Layer]

As shown in FIG. 1, the Mg deficiency preventing layer 50 is provided on the upper surface 401 of the piezoelectric layer 40 and is provided between the piezoelectric layer 40 and the second electrode 60.

The Mg deficiency preventing layer 50 has a function of reducing an outflow of Mg from the piezoelectric layer 40. The Mg deficiency preventing layer 50 contains a compound containing Mg by 30 atom % or greater, substantially contains a compound containing Mg by 30 atom % or greater, and preferably consists of a compound containing Mg by 30 atom % or greater.

The Mg content in the compound contained in the Mg deficiency preventing layer 50 is preferably 30 atom % to 90 atom %, more preferably 33 atom % to 80 atom %, and even more preferably 40 atom % to 70 atom %. When the Mg content is 30 atom % to 90 atom %, the Mg deficiency preventing layer 50 can supply Mg by an amount proportional to the outflow from the piezoelectric layer 40.

As the Mg deficiency preventing layer 50, MgO, MgF₂, Mg₂Si, and the like can be used. One of these may be used alone, or a combination of two or more of these may be used.

The Mg deficiency preventing layer 50 may be formed by sputtering, chemical vapor deposition (CVD), the sol-gel method, and the like.

The thickness of the Mg deficiency preventing layer 50 is preferably 10 nm to 100 nm, more preferably 10 nm to 50 nm, and yet more preferably 10 nm to 25 nm. When the thickness of the Mg deficiency preventing layer 50 is 10 nm to 100 nm, Mg sublimation from the piezoelectric layer 40 can be suppressed.

The thickness of the Mg deficiency preventing layer 50 is preferably equal to or less than 10%, more preferably equal to or less than 8%, and even more preferably equal to or less than 6% the thickness of the piezoelectric layer 40. When the thickness of the Mg deficiency preventing layer 50 is equal to or less than 10% the thickness of the piezoelectric layer 40, the Mg deficiency preventing layer 50 can avoid having any effects on the resonance characteristics of the piezoelectric layer 40.

### [Second Electrode]

As shown in FIG. 1, the second electrode 60 is provided on an upper main surface (upper surface) 501 of the Mg deficiency preventing layer 50. The second electrode 60 can be formed of any material having conductivity, and the same material as that of the first electrode 30 can be used.

Like the first electrode 30, the second electrode 60 may be formed on a part or the entire surface of the upper surface 501 of the Mg deficiency preventing layer 50 in a thin film shape, or in any appropriate shape. For example, when the first electrode 30 is provided in the form of a plurality of parallel stripe patterns, the second electrodes 60 may be provided in the form of a plurality of parallel stripe patterns in a direction orthogonal to the direction in which the stripes of the first electrode 30 extend in a plan view.

The thickness of the second electrode 60 can be appropriately designed, and is, for example, preferably 20 nm to 300 nm. When the thickness of the second electrode 60 is in the above preferable range, the function as an electrode can be exhibited and the piezoelectric element 1A can be reduced in thickness.

The method for producing the piezoelectric element 1A is not particularly limited, and any suitable production method may be used. An example of the method for producing the piezoelectric element 1A will be described below.

First, the acoustic mirror layer 20 is formed on the upper surface 101 of the support substrate 10 having a predetermined size, by alternately laminating the high acoustic impedance layer 21 and the low acoustic impedance layer 22 as a set of a high acoustic impedance layer 21 and a low acoustic impedance layer 22.

The method for forming the high acoustic impedance layer 21 and the low acoustic impedance layer 22 is not particularly limited, and may be either a dry process or a wet process. When the dry process is used as the method for forming the high acoustic impedance layer 21 and the low acoustic impedance layer 22, a high acoustic impedance layer 21 and a low acoustic impedance layer 22 that are thin can be easily formed.

Examples of the dry process include sputtering, vapor deposition, and the like, and examples of the wet process include plating and the like.

As sputtering, a sputtering method such as Direct-Current (DC) or Radio-Frequency (RF) magnetron sputtering can be used.

By using sputtering as the method for forming the high acoustic impedance layer 21 and the low acoustic impedance layer 22, it is possible to form the high acoustic impedance layer 21 and the low acoustic impedance layer 22 that are dense and thin easily. Therefore, sputtering is preferable as the method for forming the high acoustic impedance layer 21 and the low acoustic impedance layer 22.

As the high acoustic impedance layer 21, for example, a thin film or the like made of a material having a high density or bulk modulus, such as W, Mo, Ta₂O₅, ZnO, and the like, formed by DC or RF magnetron sputtering can be used.

As the low acoustic impedance layer 22, for example, an oxide such as SiO₂ film and the like formed by DC or RF magnetron sputtering can be used.

Next, the first electrode 30 is deposited (formed) on the upper surface 201 of the acoustic mirror layer 20. The method for forming the first electrode 30 is not particularly limited, and any of a dry process or a wet process may be used, as in the method for forming the high acoustic impedance layer 21 and the low acoustic impedance layer 22. Since the details of the dry process and the wet process are the same as those in the method for forming the high acoustic impedance layer 21 and the low acoustic impedance layer 22, the details will be omitted.

The first electrode 30 may be formed on the entirety of the upper surface 201 of the acoustic mirror layer 20. Further, the first electrode 30 may be formed in a pattern having a predetermined shape by etching or the like, to be formed in any appropriate shape. For example, the first electrode 30 may be patterned in stripe shapes to be provided in the form of a plurality of stripes.

Next, the piezoelectric layer 40 is formed on the upper surface 301 of the first electrode 30. For example, using a target containing Mg and the elements constituting the piezoelectric material, Mg and the piezoelectric material may be deposited by a sputtering method such as DC or RF magnetron sputtering in a mixed gas atmosphere containing an inert gas such as Ar or the like and a small amount of oxygen. Through sputtering of Mg and the piezoelectric material onto the first electrode 30, the piezoelectric layer 40 containing the piezoelectric material doped with Mg can be formed.

The laminate composed of the support substrate 10, the acoustic mirror layer 20, and the first electrode 30 may be set on a film deposition plate serving as an anode in the film deposition chamber of a sputtering apparatus. The film deposition plate may be, for example, rotatable. By setting the laminate composed of the support substrate 10, the acoustic mirror layer 20, and the first electrode 30 on the film deposition plate, it is possible to deposit the piezoelectric layer 40 on the first electrode 30 batch-wise.

The laminate composed of the support substrate 10, the acoustic mirror layer 20, and the first electrode 30 may be wound on a drum roll, which is a film deposition roll, as an alternative anode to the film deposition plate. By setting the drum roll in the film deposition chamber, it is possible to deposit the piezoelectric layer 40 continuously on the first electrode 30 while conveying the laminate composed of the support substrate 10, the acoustic mirror layer 20, and the first electrode 30 in a roll-to-roll manner.

The target containing Mg and the elements constituting the piezoelectric material is used as a cathode. The target is set so as to face the film deposition plate in the sputtering apparatus with an interval therebetween.

When the piezoelectric material doped with Mg contains, for example, a wurtzite crystal material, the target may include a single target or a plurality of targets containing Mg and the materials constituting the wurtzite crystal material to be contained in the piezoelectric layer 40 as a main component. By using a multi-target sputtering method when using a plurality of targets as the cathode, or by using a single-target sputtering method when using a single target as the cathode, it is possible to form the piezoelectric layer 40 containing the wurtzite crystal material doped with Mg on the first electrode 30.

When using a plurality of targets as the cathode, each target contains Mg and the materials constituting the wurtzite crystal material to be contained as a main component in the piezoelectric layer 40. As the plurality of targets, for example, a target containing Mg, a target containing Zn, a target containing Si or Sn, and a target containing Al may be used, or a target consisting of Mg and a target consisting of the wurtzite crystal material may be used. As each target, an oxygen-containing metal oxide target may be used. The plurality of targets may be set in the film deposition chamber at intervals. At the sputtering, the power to be applied to each target may be adjusted in accordance with the types of Mg and the wurtzite crystal material to be contained in the piezoelectric layer 40 and the like, such that the atomic ratio between the respective materials constituting the piezoelectric layer 40 to be doped with Mg may be adjusted.

When using a single target as the cathode, the single target contains Mg and the wurtzite crystal material to be contained in the piezoelectric layer 40. When using a single target, an alloy target in which the atomic ratios among Mg and the materials constituting the wurtzite crystal material to be contained in the piezoelectric layer 40 are adjusted can be used, and an alloy target containing a wurtzite crystal material to which Mg is previously added at a predetermined ratio can be used. As the single target, for example, an alloy target containing Mg, Zn, Si or Sn, and Al can be used. As the alloy target, a metal oxide target containing Mg, a wurtzite crystal material, and oxygen can be used.

When the piezoelectric material doped with Mg is, for example, MgZnO containing MgO and ZnO, which is the wurtzite crystal material, at a predetermined mass ratio, a multi-target sputtering method using a target composed of an MgO sintered compact and a target composed of a ZnO sintered compact can be used. As another method, a single-target sputtering method using an alloy target containing MgO and ZnO, such as a target composed of a ZnO sintered compact to which MgO is previously added at a predetermined ratio, can be used.

In the case of using the multi-target sputtering method, a multi-target sputtering apparatus is used as the sputtering apparatus, and, for example, a mixed gas containing: inert gas such as Ar or the like; and oxygen is supplied into the multi-target sputtering apparatus, to form a mixed gas atmosphere containing inert gas and oxygen. By simultaneously and independently sputtering a target composed of an MgO sintered compact and a target composed of a ZnO sintered compact onto the first electrode 30 under the mixed gas atmosphere, it is possible to deposit the piezoelectric layer 40 composed of MgZnO on the first electrode 30.

In the case of using the single-target sputtering method, by sputtering a target composed of a ZnO sintered compact to which MgO is previously added at a predetermined ratio using a sputtering apparatus in a mixed gas atmosphere containing: inert gas such as Ar or the like; and oxygen, it is possible to deposit the piezoelectric layer 40 composed of MgZnO on the first electrode 30.

The gas atmosphere for sputtering is not limited to the mixed gas atmosphere containing inert gas and oxygen, and may be an inert gas atmosphere.

The pressure in the gas atmosphere for sputtering may be suitably determined in accordance with the type of the piezoelectric material, the sputtering method, and the like, and may be, for example, 0.1 Pa to 2.0 Pa.

The deposition temperature at which the piezoelectric layer 40 is deposited is not particularly limited, and may be suitably selected in accordance with the layer structure of the piezoelectric element 1A and the like. The piezoelectric layer 40 may be deposited at, for example, 150° C. or lower.

By using the sputtering method for deposition of the first electrode 30 and the piezoelectric layer 40, it is possible to form uniform films having a strong adhesion force while keeping the composition ratio in the compound target almost unchanged. Furthermore, only by time control, it is possible to accurately form the first electrode 30 and the piezoelectric layer 40 having a desired thickness.

The piezoelectric layer 40 may be formed by laminating a plurality of thin films made of a piezoelectric material doped with Mg.

Next, the Mg deficiency preventing layer 50 is formed on the upper surface 401 of the piezoelectric layer 40. The method for forming the Mg deficiency preventing layer 50 is not particularly limited, and either a dry process or a wet process may be used as in the method for forming the high acoustic impedance layer 21 and the low acoustic impedance layer 22. Since the details of the dry process and the wet process are the same as in the method for forming the high acoustic impedance layer 21 and the low acoustic impedance layer 22, the details thereof will be omitted.

Next, the second electrode 60 having a predetermined shape is formed on the upper surface 501 of the Mg deficiency preventing layer 50. The second electrode 60 can be formed using the same method as used for the first electrode 30.

The thickness of the second electrode 60 can be appropriately designed, and may be, for example, 20 nm to 300 nm.

The second electrode 60 may be formed on the entirety of the upper surface 501 of the Mg deficiency preventing layer 50, or may be formed in an arbitrary shape. For example, when the first electrode 30 is formed in a stripe shape, he second electrodes 60 may be formed in the form of a plurality of stripe shapes in the direction orthogonal to the direction in which the stripes of the first electrode 30 extend in a plan view of the piezoelectric element 1A.

When the second electrode 60 is formed on the upper surface 501 of the Mg deficiency preventing layer 50, the piezoelectric element 1A is formed.

After the formation of the second electrode 60, the entire piezoelectric element 1A may be heat-treated at a temperature lower than the melting point or the glass transition point of the support substrate 10 (for example, 130° C.). By this heat treatment, the first electrode 30 and the second electrode 60 can be crystallized and reduced in resistance. The heat treatment is not indispensable, and does not need to be performed after the formation of the piezoelectric element 1A in a case where the support substrate 10 is made of a material that is not heat-resistant, and the like.

Thus, the piezoelectric element 1A according to this embodiment includes the support substrate 10, the acoustic mirror layer 20, the first electrode 30, the piezoelectric layer 40, the Mg deficiency preventing layer 50, and the second electrode 60. The piezoelectric layer 40 contains a piezoelectric material doped with Mg, and the Mg deficiency preventing layer 50 is provided on the upper surface 401 of the piezoelectric layer 40 containing Mg. As a result, sublimation of Mg contained in the piezoelectric layer 40 can be suppressed, and generation of defects such as voids in the surface of the piezoelectric layer 40 can be suppressed, and deterioration of the piezoelectric layer 40 can be suppressed. Therefore, the piezoelectric element 1A can suppress deterioration of the piezoelectric characteristics of the piezoelectric layer 40. Therefore, the piezoelectric element 1A can maintain the piezoelectric characteristics for a long time.

The piezoelectric characteristics of the piezoelectric element 1A can be evaluated by measuring the piezoelectric constant d₃₃ (unit: pC/N) of the piezoelectric element 1A. The piezoelectric constant d33 is a value indicating the stretch mode in the polarization direction, and is expressed as the amount of polarization charge per unit pressure applied in the polarization direction. The piezoelectric constant d33 represents the stretch mode of the piezoelectric element 1A in the direction of film thickness, i.e., in the direction of the c-axis.

The piezoelectric constant d33 is evaluated according to the following procedure. The piezoelectric element 1A is placed on a stage with the first electrode 30 facing downward, a predetermined pressure is applied from above the upper surface of the piezoelectric element 1A with an indenter, and the electric charge generated by the polarization in the direction of the c-axis (film thickness) is measured. The value obtained by dividing the amount of electric charge generated when the applied load is changed from 5 N to 6 N by 1 N, which is the load difference, is used as the value of the piezoelectric constant d₃₃.

In the piezoelectric element 1A, the Mg deficiency preventing layer 50 can contain a compound containing Mg by 30 atom % or greater. Thus, even when Mg sublimates and escapes from the piezoelectric layer 40, the piezoelectric element 1A can supply an amount of Mg corresponding to the amount removed from the Mg deficiency preventing layer 50 into the piezoelectric layer 40. Therefore, since the piezoelectric element 1A can more reliably suppress deterioration of the piezoelectric layer 40, deterioration of the piezoelectric characteristics of the piezoelectric layer 40 can be better suppressed. Therefore, the piezoelectric element 1A can more reliably maintain the piezoelectric characteristics for a long time.

In the piezoelectric element 1A, the Mg deficiency preventing layer 50 can be formed of at least one selected from MgO, MgF₂, and Mg₂Si. Since MgO, MgF₂, and Mg₂Si easily move from the Mg deficiency preventing layer 50 into the piezoelectric layer 40 and easily enter the gap formed by removal of Mg from the piezoelectric layer 40, the Mg deficiency preventing layer 50 can reliably supply Mg to the piezoelectric layer 40 and reliably suppress deterioration of the piezoelectric layer 40. Therefore, the piezoelectric element 1A can suppress deterioration of the piezoelectric characteristics of the piezoelectric layer 40 and reliably maintain the piezoelectric characteristics through use for a long time.

In the piezoelectric element 1A, the thickness of the Mg deficiency preventing layer 50 may be 10 nm or greater. Thus, the Mg deficiency preventing layer 50 can reliably suppress sublimation of Mg contained in the piezoelectric layer 40 and reliably suppress deterioration of the piezoelectric layer 40. Therefore, the piezoelectric element 1A can suppress deterioration of the piezoelectric characteristics of the piezoelectric layer 40 and reliably maintain the piezoelectric characteristics through use for a long time.

In the piezoelectric element 1A, the thickness of the Mg deficiency preventing layer 50 equal to or less than 10% that of the piezoelectric layer 40. Thus, the Mg deficiency preventing layer 50 can avoid affecting the resonance characteristics of the piezoelectric layer 40. Therefore, the piezoelectric element 1A can suppress deterioration of the piezoelectric characteristics of the piezoelectric layer 40 and the piezoelectric characteristics can be reliably maintained through use for a long time.

In the piezoelectric element 1A, the piezoelectric layer 40 can contain MgZnO as a piezoelectric material. In general, there is a trade-off relationship between the K factor and the Q factor of a piezoelectric layer formed by doping a piezoelectric material with another element. Therefore, when the K factor needed in the high-frequency band such as the 5G band and the like is secured, the Q factor tends to decrease in use of a piezoelectric element in, for example, a high-frequency filter and the like for extracting only signals in the high-frequency band and removing signals in the other frequency bands. When the piezoelectric layer 40 contains MgZnO as a piezoelectric material, the K factor and the Q factor can both be satisfied even in the high-frequency band, with MgZnO free of trade-off between the K factor and the Q factor with respect to the Mg concentration. On the other hand, MgZnO, which is a complex oxide, tends to allow Mg to sublimate easily during use, which is likely to cause characteristic variation. In this embodiment, even when the piezoelectric layer 40 contains MgZnO as a piezoelectric material, the piezoelectric element 1A can stably exhibit the piezoelectric characteristics even in the high-frequency band of, for example, a high-frequency filter and the like, because the Mg deficiency preventing layer 50 can supplement Mg.

Since the piezoelectric element 1A can keep excellent piezoelectric characteristics for a long time, it can be used in electronic devices of various applications as an electronic component utilizing the normal piezoelectric effect or the reverse piezoelectric effect in the electronic devices.

The piezoelectric element 1A can be used as an electronic component utilizing the normal piezoelectric effect in, for example, various sensors, such as force sensors for touch panels, pressure sensors, acceleration sensors, angular velocity sensors, acoustic emission (AE) sensors, crime prevention sensors, care/watch sensors, impact sensors, wearable sensors, biological signal sensors, trapping prevention sensors for vehicles, bumper crash sensors for vehicles, air flow rate sensors for vehicles, weather detection sensors, fire detection sensors, underwater acoustic sensors, tactile sensors, pressure distribution sensors, and the like.

The piezoelectric element 1A can be used as an electronic component utilizing the reverse piezoelectric effect in, for example, piezoelectric acoustic components, such as loudspeakers, buzzers, microphones, and the like, transducers, high-frequency filters, actuators, optical scanners, inkjet printer heads, MEMS mirrors for scanners, ultrasonic motors, piezoelectric motors, and the like. In particular, since piezoelectric element 1A can be used in applications where high piezoelectric characteristics are required, especially in the high-frequency band, it can be suitably used for, for example, high-frequency filters. High-frequency filters include Surface Acoustic Wave (SAW) filters using surface acoustic waves, filters using Bulk Acoustic Waves (BAW), and the like. The piezoelectric element 1A can be effectively used as a BAW filter because it can keep excellent piezoelectric characteristics for a long time even in the high-frequency band.

### Modified Examples

In this embodiment, the piezoelectric element 1A is not limited to the above-described configuration, and may have other configurations as long as it includes the Mg deficiency preventing layer 50 and can maintain the piezoelectric characteristics of piezoelectric layer 40 by adding Mg to the piezoelectric layer 40. Examples of other configurations of the piezoelectric element 1A are shown below.

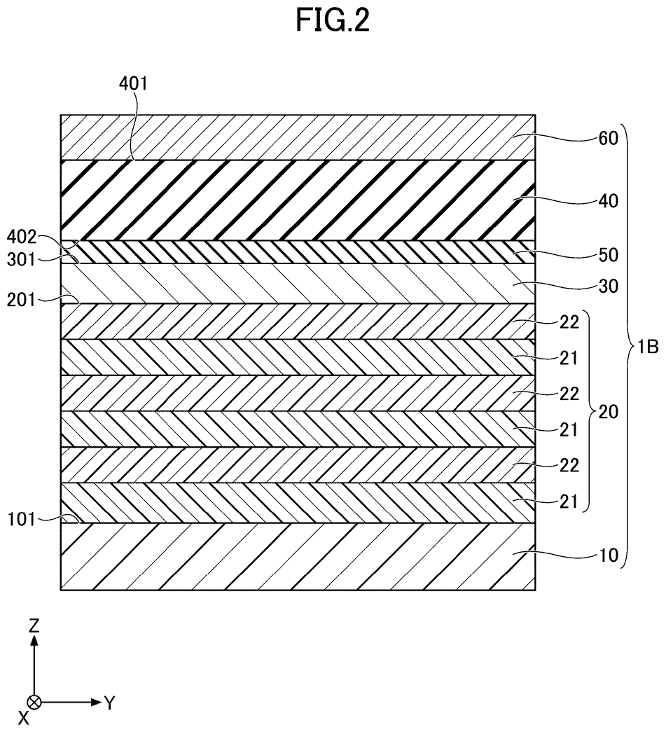

As shown in FIG. 2, a piezoelectric element 1B may include the Mg deficiency preventing layer 50 on a lower surface 402 of the piezoelectric layer 40. That is, the piezoelectric element 1B may include the Mg deficiency preventing layer 50 between the first electrode 30 and the piezoelectric layer 40. In this case, the piezoelectric element 1B including the Mg deficiency preventing layer 50 on the lower surface 402 of the piezoelectric layer 40 can suppress generation of voids in the lower surface 402 of the piezoelectric layer 40 due to Mg deficiency through Mg slipping out from the lower surface 402 of the piezoelectric layer 40. Therefore, the effect of suppressing deterioration of the piezoelectric layer 40 can be maintained.

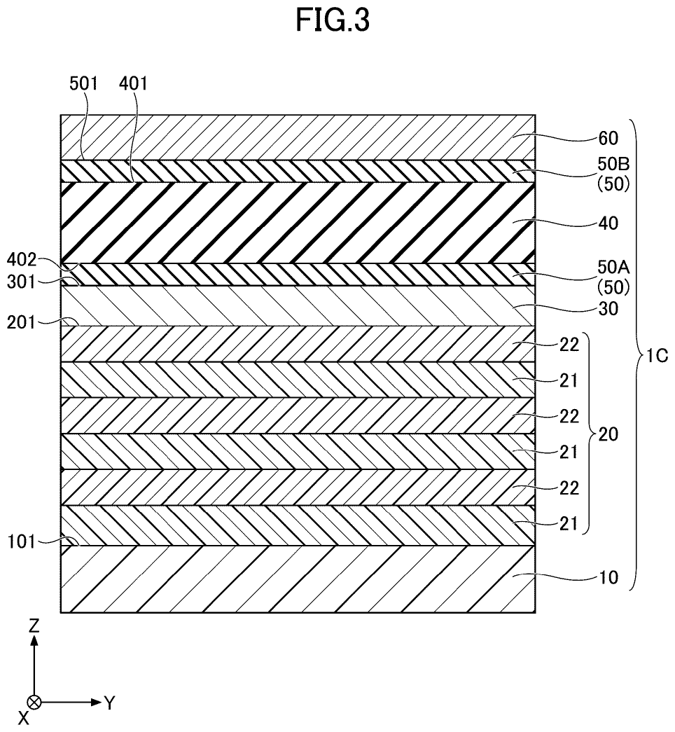

As shown in FIG. 3, a piezoelectric element 1C may include the Mg deficiency preventing layer 50 on the upper surface 401 and the lower surface 402 of the piezoelectric layer 40 so as to cover the piezoelectric layer 40 in contact with the piezoelectric layer 40. That is, the piezoelectric element 1C may include the Mg deficiency preventing layer 50 between the first electrode 30 and the piezoelectric layer 40 and between the piezoelectric layer 40 and the second electrode 60. In this case, the piezoelectric element 1C including the Mg deficiency preventing layer 50 on the upper surface 401 and the lower surface 402 of the piezoelectric layer 40 can better suppress generation of voids in the upper surface 401 and the lower surface 402 of the piezoelectric layer 40 due to Mg deficiency through Mg deficiency through Mg slipping out from the upper surface 401 and the lower surface 402 of the piezoelectric layer 40. Therefore, the effect of suppressing deterioration of the piezoelectric layer 40 can be more reliably maintained.

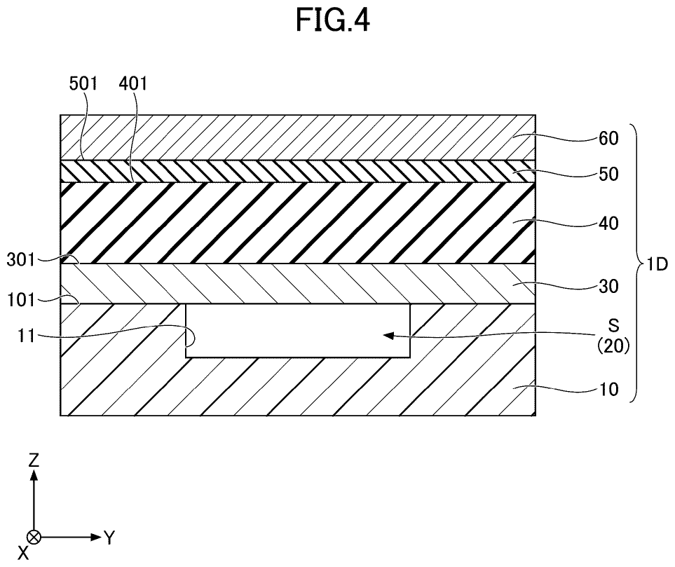

In this embodiment, the acoustic mirror layer 20 of the piezoelectric element 1A is formed of an acoustic multilayer film. However, the acoustic mirror layer 20 may be formed of a space. For example, as shown in FIG. 4, a piezoelectric element 1D may include a recess 11 in the upper surface 101 of the support substrate 10, such that a space S formed between the recess 11 of the support substrate 10 and the first electrode 30 functions as the acoustic mirror layer 20. Since the space S of the piezoelectric element 1E can function as the acoustic mirror layer 20, the first electrode 30 can be directly provided on the upper surface 101 of the support substrate 10. As a result, the piezoelectric element 1E can be reduced in overall thickness and can be reduced in size.

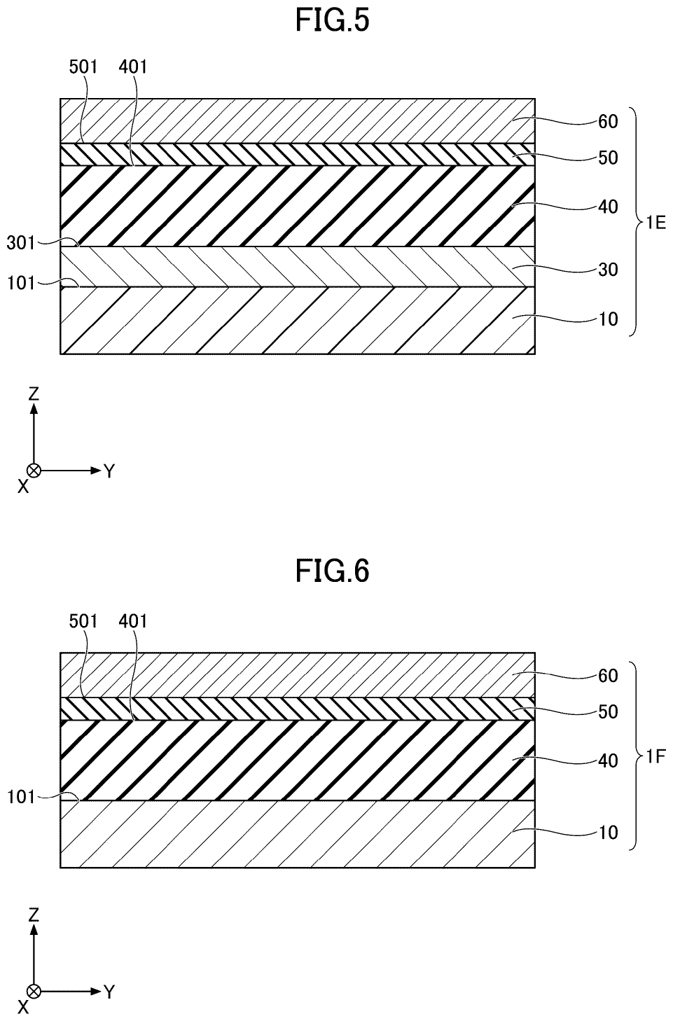

In this embodiment, the piezoelectric element 1A does not need to include the acoustic mirror layer 20. As shown in FIG. 5, a piezoelectric element 1E may include the support substrate 10, the first electrode 30, the piezoelectric layer 40, the Mg deficiency preventing layer 50, and the second electrode 60, which are laminated in this order from the support substrate 10 side.

In this case, the support substrate 10 may be a conductive substrate. When the support substrate 10 is a conductive substrate, the piezoelectric element 1A does not need to include the first electrode 30 because the support substrate 10 can also function as the first electrode. For example, as shown in FIG. 6, a piezoelectric element 1F may include the support substrate 10, the piezoelectric layer 40, the Mg deficiency preventing layer 50, and the second electrode 60 that are laminated in this order from the support substrate 10 side. The support substrate 10 may be a metal plate, or a conductive transparent substrate such as ITO, IZO, IZTO, IGZO, and the like. When the support substrate 10 is a metal plate, a metal film such as Al foil, Cu foil, Al—Ti alloy foil, Cu—Ti alloy foil, stainless steel foil, and the like may be used. When the thickness of the metal film is small, the support substrate 10 has an increased flexibility. Therefore, a metal close adhesion film such as Ti, Ni, and the like may be inserted between the support substrate 10 and the piezoelectric layer 40. As shown in FIG. 6, the thickness of the piezoelectric element 1F can be reduced by an amount corresponding to the first electrode 30. As a result, the piezoelectric element 1F can be reduced in overall thickness and can be reduced in size.

Although the embodiments have been described as above, the above embodiments are presented as examples, and the present invention is not limited by the above embodiments. The above embodiments can be implemented in various other forms, and various combinations, omissions, substitutions, modifications, and the like are applicable without departing from the spirit of the invention. These embodiments and modifications thereof are included in the scope and spirit of the invention, as well as in the scope of the invention described in the claims and equivalents thereof.

Aspects of the present invention are, for example, as follows.

<1> A piezoelectric element, including:
a first electrode, a piezoelectric layer containing a piezoelectric material doped with Mg, and a second electrode, which are laminated in this order on a support substrate; and
an Mg deficiency preventing layer configured to reduce an outflow of Mg from the piezoelectric layer, the Mg deficiency preventing layer being provided at at least one of a location between the first electrode and the piezoelectric layer, and a location between the piezoelectric layer and the second electrode.
   <2> The piezoelectric element according to <1>,
wherein the Mg deficiency preventing layer is composed of a compound containing Mg by 30 atom % or greater.
<3> The piezoelectric element according to <1> or <2>,
wherein the Mg deficiency preventing layer contains at least one component selected from MgO, MgF₂, and Mg₂Si.
   <4> The piezoelectric element according to any one of <1> to <3>,
wherein the Mg deficiency preventing layer has a thickness of 10 nm or greater.
   <5> The piezoelectric element according to any one of <1> to <4>,
wherein the Mg deficiency preventing layer has a thickness that is equal to or less than 10% that of the piezoelectric layer.
   <6> The piezoelectric element according to any one of <1> to <5>,
wherein the piezoelectric layer is Zno doped with Mg.
   <7> The piezoelectric element according to any one of <1> to <6>, further including:
an acoustic mirror layer between the support substrate and the first electrode,
wherein the acoustic mirror layer is a laminate in which at least one pair of a high acoustic impedance layer and a low acoustic impedance layer arranged alternately is laminated, or is a gap formed between the support substrate and the first electrode.
   <8> An electronic device, including:
the piezoelectric element according to any one of <1> to <7>.

This application claims priority based on Japanese Patent Application No. 2022-157636, filed with the Japan Patent Office on Sep. 30, 2022, and all contents described in the application are incorporated herein.

### REFERENCE SIGNS LIST

1A to 1F piezoelectric element
10 support substrate
20 acoustic mirror layer
30 first electrode
40 piezoelectric layer
50 Mg deficiency preventing layer
60 second electrode
S space

1. A piezoelectric element, comprising:
a first electrode, a piezoelectric layer containing a piezoelectric material doped with Mg, and a second electrode, which are laminated in this order on a supporting substrate; and
an Mg deficiency preventing layer configured to reduce an outflow of Mg from the piezoelectric layer, the Mg deficiency preventing layer being provided at at least one of a location between the first electrode and the piezoelectric layer, and a location between the piezoelectric layer and the second electrode.

2. The piezoelectric element according to claim 1,
wherein the Mg deficiency preventing layer contains a compound containing Mg by 30 atom % or greater.

3. The piezoelectric element according to claim 1,
wherein the Mg deficiency preventing layer contains at least one component selected from MgO, MgF₂, and Mg₂Si.

4. The piezoelectric element according to claim 1,
wherein the Mg deficiency preventing layer has a thickness of 10 nm or greater.

5. The piezoelectric element according to claim 1,
wherein the Mg deficiency preventing layer has a thickness that is equal to or less than 10% that of the piezoelectric layer.

6. The piezoelectric element according to claim 1,
wherein the piezoelectric layer is ZnO doped with Mg.

7. The piezoelectric element according to claim 1, further comprising:
an acoustic mirror layer between the support substrate and the first electrode,
wherein the acoustic mirror layer is a laminate in which at least one pair of a high acoustic impedance layer and a low acoustic impedance layer arranged alternately is laminated, or is a gap formed between the support substrate and the first electrode.

8. An electronic device, comprising:
the piezoelectric element of claim 1.
